(19) United States
(12) Patent Application Publication
(10) Pub. No.: US 2020/0203263 A1
(43) Pub. Date: Jun. 25, 2020

(54) LOW COST RELIABLE FAN-OUT CHIP SCALE PACKAGES

(71) Applicant: Texas Instruments Incorporated, Dallas, TX (US)

(72) Inventor: Sreenivasan K. Koduri, Allen, TX (US)

(73) Assignee: Texas Instruments Incorporated, Dallas, TX (US)

(21) Appl. No.: 16/225,106

(22) Filed: Dec. 19, 2018

(51) Int. Cl. H01L 23/498; H01L 23/31; H01L 23/00; H01L 23/42; H01L 21/56; H01L 21/48

(52) U.S. Cl. CPC H01L 23/49816; H01L 23/3107; H01L 24/48; H01L 23/42; H01L 2224/48227; H01L 21/4853; H01L 21/561; H01L 24/96; H01L 21/568

(57) ABSTRACT

A microelectronic device, in a fan-out chip scale package, has a die and an encapsulation material at least partially surrounding the die. The microelectronic device includes bump bond pads adjacent to the die that are exposed by the encapsulation material, the bump bond pads being free of photolithographically-defined structures. Wire bonds connect the die to the bump bond pads. The microelectronic device is formed by mounting the die on a carrier, and forming the bump bond pads adjacent to the die without using a photolithographic process. Wire bonds are formed between the die and the bump bond pads. The die, the wire bonds, and the bump bond pads are covered with an encapsulation material, and the carrier is subsequently removed, exposing the bump bond pads.

### FIELD

This disclosure relates to the field of microelectronic devices. More particularly, this disclosure relates to chip scale packaging of microelectronic devices.

### BACKGROUND

Chip scale packaging of microelectronic devices provides low cost and small area. As chip sizes continue to shrink, accommodating bump bonds for the terminals of the chip becomes challenging. Expanding the packages with lead frames undesirably adds costs to the packages.

### SUMMARY

The present disclosure introduces a microelectronic device having a fan-out chip scale package, and a method for forming the microelectronic device. The microelectronic device includes a die and an encapsulation material at least partially surrounding the die. The microelectronic device further includes bump bond pads adjacent to the die that are exposed by the encapsulation material, the bump bond pads being free of photolithographically-defined structures. Wire bonds connect the die to the bump bond pads.

The microelectronic device is formed by mounting the die on a carrier, and forming the bump bond pads adjacent to the die without using a photolithographic process. Wire bonds are formed between the die and the bump bond pads. The die, the wire bonds, and the and bump bond pads are covered with an encapsulation material, and the carrier is subsequently removed, exposing the bump bond pads.

### BRIEF DESCRIPTION OF THE VIEWS OF THE DRAWINGS

FIG. 1A through FIG. 1K include perspectives, cross sections, and a top view of a microelectronic device having a fan-out chip scale package, depicted in stages of an example method of formation.

FIG. 2A through FIG. 2I include perspectives, cross sections, and a top view of a microelectronic device having a fan-out chip scale package, depicted in stages of another example method of formation.

FIG. 3A through FIG. 3J include perspectives, cross sections, and a top view of a microelectronic device having a fan-out chip scale package, depicted in stages of another example method of formation.

FIG. 4A through FIG. 4H include perspectives and cross sections of a microelectronic device having a fan-out chip scale package, depicted in stages of a further example method of formation.

FIG. 5A through FIG. 5E include perspectives, cross sections, and a top view of a microelectronic device having a fan-out chip scale package, depicted in stages of another example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

This application is related to the following U.S. patent applications: U.S. patent application Ser. No. 12/______, Attorney Docket Number TI-78742, filed concurrently with this application, U.S. patent application Ser. No. 12/______, Attorney Docket Number TI-78743, filed concurrently with this application, and U.S. patent application Ser. No. 12/______, Attorney Docket Number TI-78745, filed concurrently with this application. For applications filed concurrently with this application, with their mention in this section, these patent applications are not admitted to be prior art with respect to the present invention.

A microelectronic device has a die in a fan-out chip scale package. The fan-out chip scale package includes bump bond pads located adjacent to the die. Bump bond pads are electrically conductive pads for external connections to the microelectronic device using an electrically conductive connection material. Bump bond pads are distinguished from leads which extend from microelectronic devices having leads. The term “adjacent” in this disclosure includes cases in which the bump bond pads are separated from the die by a space. For the purposes of this disclosure, a fan-out chip scale package has bump bond pads that do not overlap with the die, and connections to the solder bumps that are formed after the die is singulated from a wafer which contained the die. In various aspects of this disclosure, the bump bond pads may include one or more wire bond studs, wire bond stitch bonds, and one or more metal layers. The die is connected to the bump bond pads by wire bonds. An encapsulation material at least partially surrounds the die and the wire bonds, and extends to the bump bond pads. An electrically conductive connection material, such as a solder or an electrically conductive adhesive, may be disposed on the bump bond pads. The bump bond pads are free of photolithographically-defined structures. For the purposes of this disclosure, photolithographically-defined structures include structures which are formed by forming a layer, using a photolithographic process to form an etch mask over the layer, and removing the layer where exposed by the etch mask. Photolithographically-defined structures include structures which are formed by using a photolithographic process to form a plating mask, and plating metal in areas exposed by the plating mask. For the purposes of this disclosure, photolithographic processes include exposing photosensitive material to patterned radiation using a photomask, exposing photosensitive material to patterned radiation using a maskless light source such as a micro-mirror system, X-ray lithography, e-beam lithography, and exposing photosensitive material to patterned radiation using scanned laser lithography.

The microelectronic device is formed by mounting the die on a carrier, and forming the bump bond pads adjacent to the die without using a photolithographic process. At least a portion of the bump bond pads are formed on the carrier. Wire bonds are formed between the die and the bump bond pads. The die, the wire bonds, and the and bump bond pads are covered with an encapsulation material, and the carrier is subsequently removed, exposing the bump bond pads. Remaining portions of the bump bond pads may be formed after the carrier is removed. The electrically conductive connection material may be formed on the bump bond pads.

For the purposes of this disclosure, the term “wire bonding” is understood to encompass bonding with round bond wire and with ribbon bond wire. Furthermore, the term “wire bonding” is understood to encompass ball bonding, stitch bonding, and wedge bonding. Similarly, the term “wire bond” is understood to encompass bonds with round bond wire and ribbon bond wire, and encompass bonds with ball bonds, stitch bonds, and wedge bonds. The term “die” is used in this disclosure to denote a single chip or more than one chip.

It is noted that terms such as top, over, under, and below may be used in this disclosure. These terms should not be construed as limiting the position or orientation of a structure or element, but should be used to provide spatial relationship between structures or elements.

The terms “parallel” and “perpendicular” are used to describe spatial relationships of elements with respect to other elements. In one aspect of this disclosure, the terms “parallel” and “perpendicular” encompass spatial relationships that are parallel or perpendicular within fabrication tolerances encountered in the fabrication of the respective elements. In another aspect, the terms “parallel” and “perpendicular” encompass spatial relationships that are parallel or perpendicular within measurement tolerances encountered when measuring the spatial relationships.

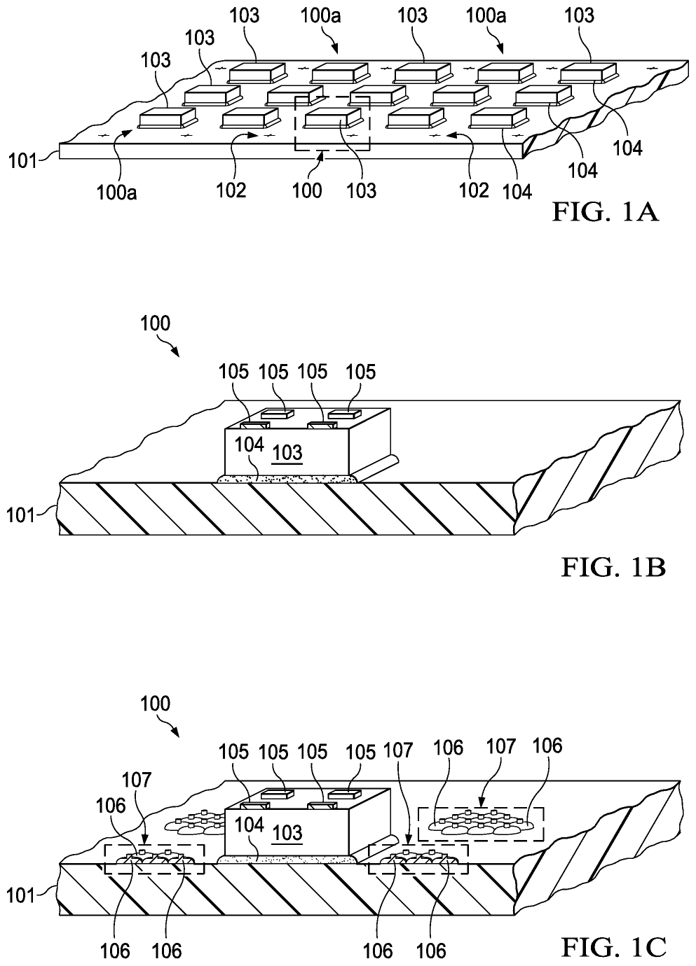

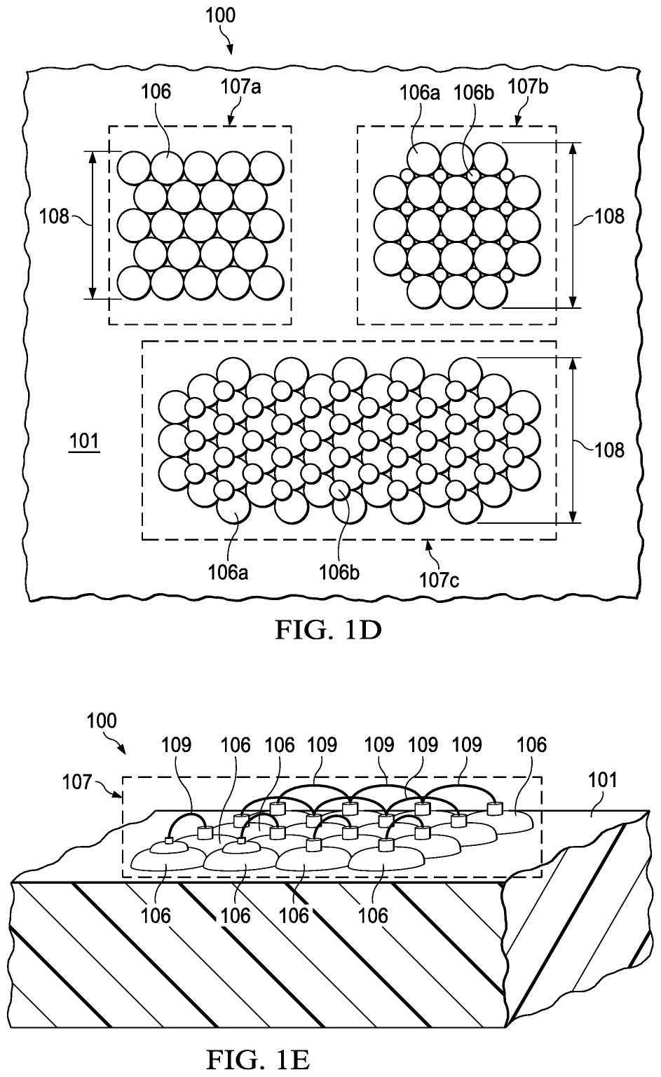

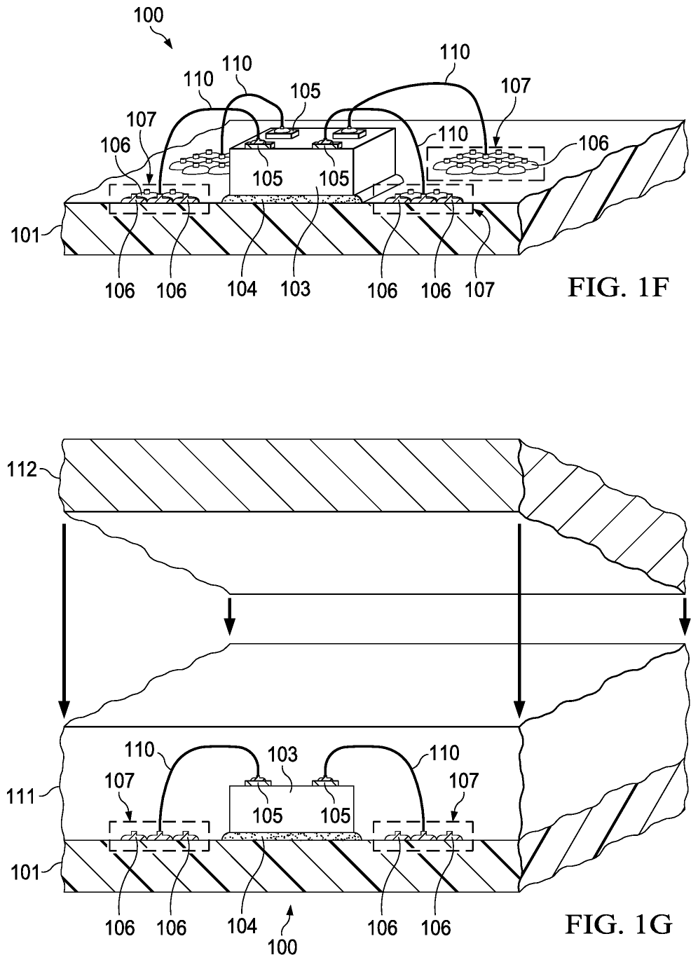

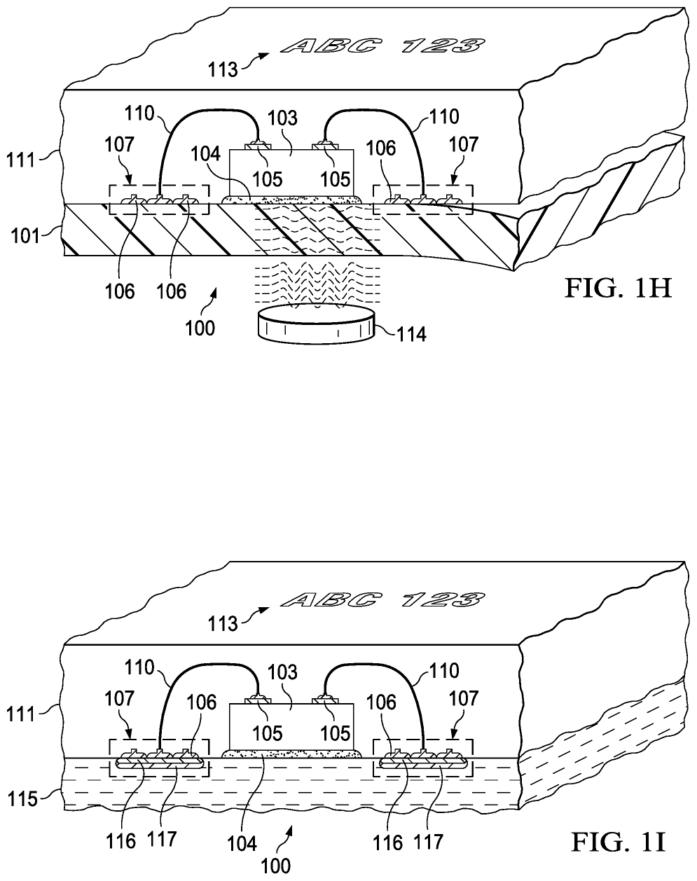

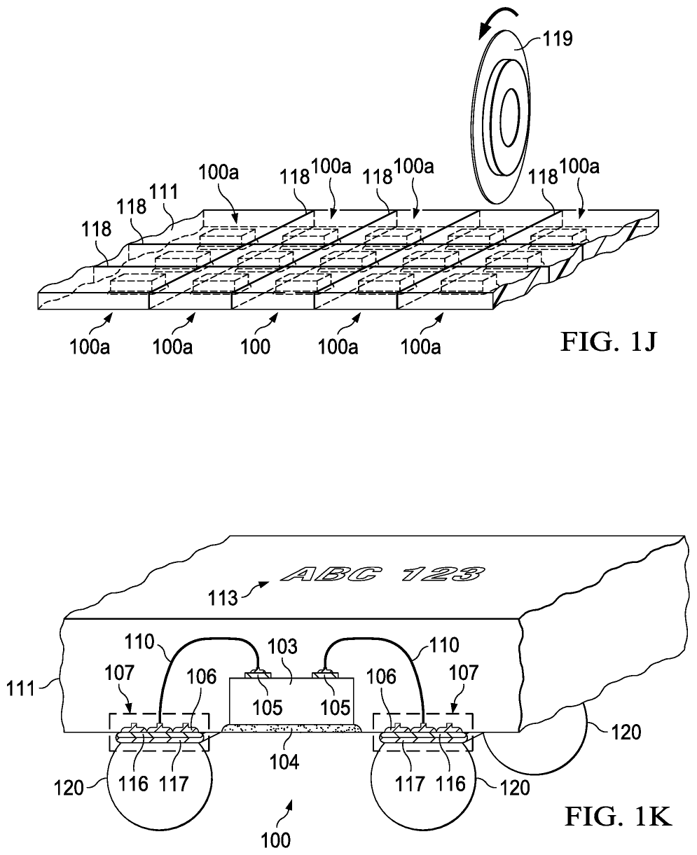

FIG. 1A through FIG. 1K include perspectives, cross sections, and a top view of a microelectronic device having a fan-out chip scale package, depicted in stages of an example method of formation. Referring to FIG. 1A, formation of the microelectronic device (100) begins by acquiring a carrier(101). The carrier (101) includes one or more materials suitable as a substrate for forming wire bond studs, and further suitable for separation from an encapsulation material, such as epoxy. In this example, the carrier (101) may be flexible, to facilitate separation from the encapsulation material. The carrier (101) may include, for example, polycarbonate, phenolic, or acrylic material. The carrier (101) may also include particles of a hard inorganic material, such as aluminum oxide or diamond, to provide increased hardness. The carrier (101) may have a laminated structure, with a thin, hard surface layer of glass or metal, attached to a flexible substrate. Other compositions and structures for the carrier (101) are within the scope of this example. The carrier (101) may have alignment marks (102) to assist subsequent placement of die on the carrier (101). The carrier (101) may have a continuous, belt-like configuration, or may have a flat rectangular configuration.

Multiple die (103) are attached to the carrier (101). One of the die (103) is attached to the carrier (101) in an area for the microelectronic device (100), and additional die (103) are attached to the carrier (101) in separate areas for additional microelectronic devices (100a). The die (103) may be manifested as integrated circuits, discrete semiconductor components, electro-optical devices, microelectrical mechanical systems (MEMS) devices, or other microelectronic die. The die (103) may all be substantially similar devices, for example, may all be instances of a particular power transistor. Alternatively, the die (103) may include more than one device type.

The die (103) may be attached to the carrier by a die attach material (104), such as an adhesive. The die attach material (104) may be electrically non-conductive, to electrically isolate the die (103). The die attach material (104) may include, for example, epoxy. The die attach material (104) may include particles such as copper or silver, coated with an insulating layer, to increase thermal conductivity from the die (103) to an exterior of the microelectronic device (100).

FIG. 1B shows the microelectronic device (100) in more detail. The die (103) may have terminals (105) for electrical connections to components in the die (103). The terminals (105) may be manifested as bond pads, or may be manifested as circuit nodes, such as transistor source and drain nodes. The terminals (105) may include materials suitable for wire bonding, such as aluminum, copper, gold, or platinum.

Referring to FIG. 1C, wire bond studs (106) are formed on the carrier (101) adjacent to the die (103), using a wire bonding process. The wire bond studs (106) may be formed by pressing a free air ball of a bond wire onto the carrier (101) with a wire bonding capillary to form a stud, and subsequently severing the bond wire proximate to the stud. The wire bond studs (106) may include primarily copper or gold, and may have some nickel or palladium from a barrier layer around the bond wire. The wire bond studs (106) are formed in contiguous groups to form initial portions of bump bond pads (107). Forming the bump bond pads (107) without using a photolithographic process may advantageously reduce fabrication cost and fabrication complexity of the microelectronic device (100).

FIG. 1D depicts example configurations of the wire bond studs (106) in the bump bond pads (107) of FIG. 1C. A first bump bond pad (107a) may have a hexagonal array configuration, with wire bond studs (106) of substantially equal sizes, as a result of being formed with equal diameter bond wire and equal force on the wire bonding capillary. Adjacent wire bond studs (106) contact each other in the first bump bond pad (107a), to form a contiguous electrically conductive structure on the carrier (101). The first bump bond pad (107a) may have a minimum lateral dimension (108) of 150 microns to 300 microns. The term “lateral” refers to a direction parallel to a face of the carrier (101) on which the wire bond studs (106) are formed. The minimum lateral dimension (108) may be selected to maintain current density through the first bump bond pad (107a), during operation of the microelectronic device (100), below a target value, to provide a desired level of reliability.

A second bump bond pad (107b) may have a square array configuration, with first wire bond studs (106a) of substantially equal first sizes, and second wire bond studs (106b) of substantially equal second sizes, smaller than the first size. The second wire bond studs (106b) may be disposed between the first wire bond studs (106a) to provide a higher fill factor of electrically conductive material in the second bump bond pad (107b). Adjacent first wire bond studs (106a) and second wire bond studs (106b) contact each other in the second bump bond pad (107b), to form a contiguous electrically conductive structure on the carrier (101). The second bump bond pad (107b) may have a minimum lateral dimension (108) of 150 microns to 300 microns, to provide desired level of reliability as explained in reference to the first bump bond pad (107a).

A third bump bond pad (107c) may have a rounded rectangle configuration, with first wire bond studs (106a) of substantially equal first sizes, and second wire bond studs (106b) of substantially equal second sizes, smaller than the first size. The second wire bond studs (106b) may be disposed between the first wire bond studs (106a) to provide a higher fill factor of electrically conductive material in the third bump bond pad (107c). Adjacent first wire bond studs (106a) and second wire bond studs (106b) contact each other in the third bump bond pad (107c), to form a contiguous electrically conductive structure on the carrier (101). The third bump bond pad (107c) may have a minimum lateral dimension (108) of 150 microns to 300 microns, and may have a length significantly longer than the minimum lateral dimension (108), to provide desired level of reliability as explained in reference to the first bump bond pad (107a). The rounded rectangle configuration of the third bump bond pad (107c) may be appropriate for power and ground connections to the microelectronic device (100) of FIG. 1C, which commonly conduct significantly more current than signal connections.

FIG. 1E depicts an example structure of the wire bond studs (106) in the bump bond pads (107). A portion or all of the wire bond studs (106) in a bump bond pad (107) may be interconnected by one or more intra-pad wire bonds (109). The intra-pad wire bonds (109) may have ball bonds on the carrier (101), or on a wire bond stud (106). Each intra-pad wire bond (109) may connect two or more of the wire bond studs (106), using chained stitch bonds. The intra-pad wire bonds (109) may advantageously provide lower resistance between the wire bond studs (106) than is provided by contact between adjacent wire bond studs (106).

Referring to FIG. 1F, wire bonds (110) are formed by a wire bonding process to connect the die (103) to the bump bond pads (107). FIG. 1F depicts the wire bonds (110) as formed using round bond wire. Other types of bond wire, such as ribbon bond wire, are within the scope of this example. The wire bonds (110) may include, for example, copper wire, gold wire, or aluminum wire. Copper wire in the wire bonds (110) may optionally have a coating of palladium or nickel to reduce corrosion or oxidation of the copper wire. The wire bonds (110) may be formed with ball bonds on the die (103) and stitch bonds on the bump bond pads (107), as depicted in FIG. 1F. Alternatively, the wire bonds (110) may be formed with stitch bonds on the die (103) and ball bonds on the bump bond pads (107).

The wire bonds (110) may connect to the terminals (105) on the die (103), as depicted in FIG. 1F. The wire bonds (110) may connect each of the terminals (105) to a separate bump bond pad (107), as indicated in FIG. 1F. Alternatively, one of the bump bond pads (107) may be connected by the wire bonds (110) to two or more of the terminals (105). Similarly, one of the terminals (105) may be connected by the wire bonds (110) to two or more of the bump bond pads (107).

Referring to FIG. 1G, an encapsulation material (111) is formed over the die (103), the wire bonds (110), and the bump bond pads (107). The encapsulation material (111) may include epoxy or other material suitable for protecting the die (103) and the wire bonds (110) from moisture and contamination. The encapsulation material (111) may be formed by using a press mold (112); the press mold (112) is removed after the encapsulation material (111) is formed. Alternatively, the encapsulation material (111) may be formed by injection molding, by an additive process, or by other methods. The encapsulation material (111) extends to the carrier (101) adjacent to the die (103) and adjacent to the bump bond pads (107).

Referring to FIG. 1H, a device identification mark (113) may be formed on the encapsulation material (111). Alternatively, the device identification mark (113) may be formed at a subsequent step of the formation process.

The carrier (101) is removed from the microelectronic device (100) by separating the carrier (101) from the encapsulation material (111) and from the wire bond studs (106). Removal of the carrier (101) may be facilitated using ultrasonic vibrations applied by an ultrasonic transducer (114), as indicated in FIG. 1H. Other methods for removing the carrier (101), such as using a thermal shock, using penetrating solvents, or mechanical cleaving, are within the scope of this example. Removal of the carrier (101) exposes the bump bond pads (107).

Referring to FIG. 1I, a plating process using a plating bath (115) forms one or more metal layers of the bump bond pads (107) on the wire bond studs (106) where exposed by the encapsulation material (111). The one or more metal layers may include a base layer (116) on the wire bond studs (106), and a barrier layer (117) on the base layer (116). The chemistry of the plating bath (115) may be changed to provide desired compositions of the one or more metal layers. The plating process may be implemented as an autocatalytic electroless process or an immersion process, for example. An autocatalytic electroless process may be continued as long as needed to provide a desired thickness of the metal layer. An immersion process is substantially self-limiting, producing a metal layer that is a few nanometers thick. The base layer (116) may include a metal with a high electrical conductivity, such as copper, and may be formed to be 50 microns to 150 microns thick, to provide a low resistance for the bump bond pads (107). The barrier layer (117) may include one or more metals that reduce diffusion between metal in the base layer (116) and subsequently formed solder on the bump bond pads (107). The barrier layer (117) may include, for example, nickel, palladium, cobalt, titanium, or molybdenum. The barrier layer (117) may be formed to be 5 microns to 20 microns thick, for example. The base layer (116) and the barrier layer (117) may be characterized by a conformal configuration on the wire bond studs (106), in which the base layer (116) and the barrier layer (117) conform to contours of the wire bond studs (106), resulting from the plating process. The base layer (116) and the barrier layer (117) are parts of the bump bond pads (107), along with the wire bond studs (106), in this example. Forming the base layer (116) and the barrier layer (117) without using a photolithographic process may further reduce the fabrication cost and the fabrication complexity of the microelectronic device (100).

Referring to FIG. 1J, the microelectronic device (100) is singulated from the additional microelectronic devices (100a) by cutting through the encapsulation material (111) in singulation lanes (118) between the microelectronic device (100) and the additional microelectronic devices (100a). The microelectronic device (100) may be singulated by a saw process using a saw blade (119), as indicated in FIG. 1J. Singulating the microelectronic device (100) may be facilitated by the absence of metal in the singulation lanes (118).

Referring to FIG. 1K, an electrically conductive connection material (120) may be formed on the bump bond pads (107). In one version of this example, the electrically conductive connection material (120) may be implemented as a solder. The solder may be formed by disposing preformed solder balls on the bump bond pads (107), followed by a solder reflow process. Alternatively, the solder may be formed by disposing solder paste on the bump bond pads (107), followed by a solder reflow process. In another version of this example, the electrically conductive connection material (120) may be implemented as an electrically conductive adhesive The electrically conductive adhesive may include epoxy with metal particles such as silver, or nickel coated copper, and may be formed by a screen printing process or a material extrusion process. Optionally, the electrically conductive connection material (120) may be omitted during formation of the microelectronic device (100), and may be disposed on the bump bond pads (107) later, during an assembly process in which the microelectronic device (100) is connected to a circuit substrate.

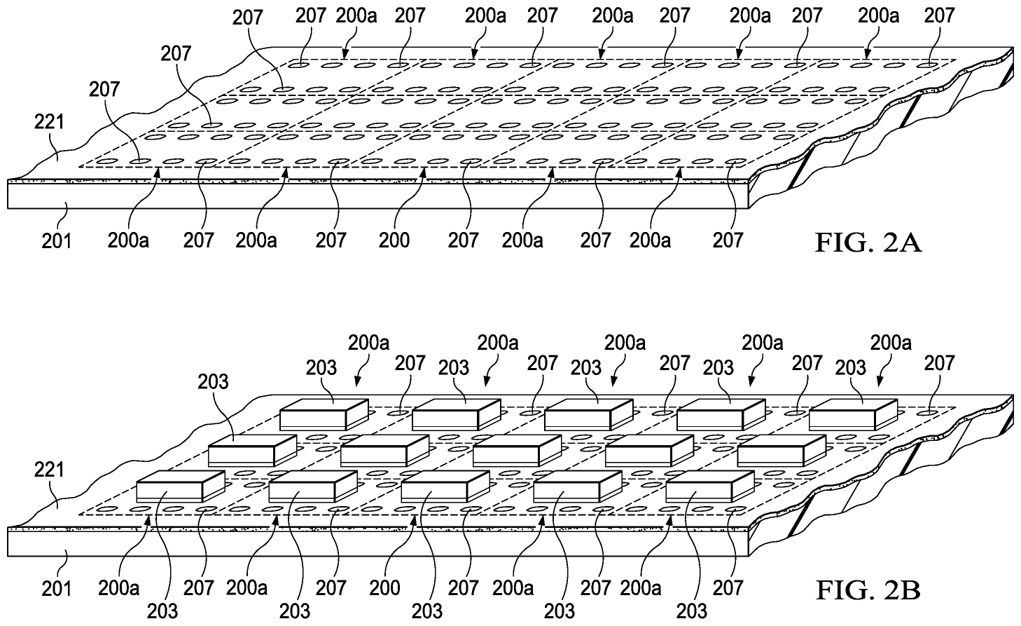

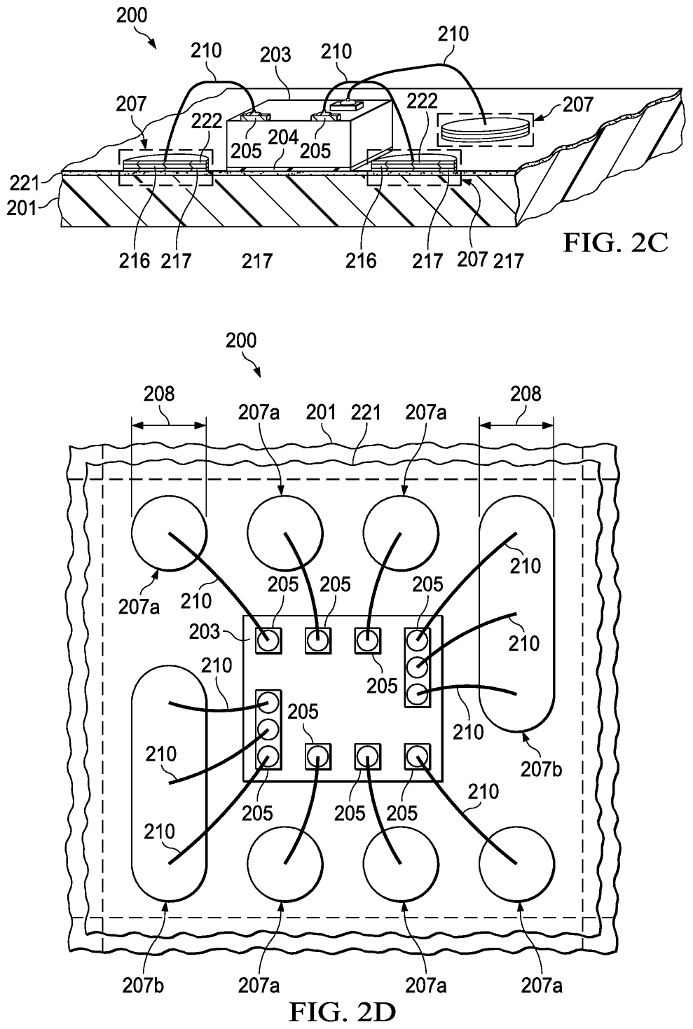

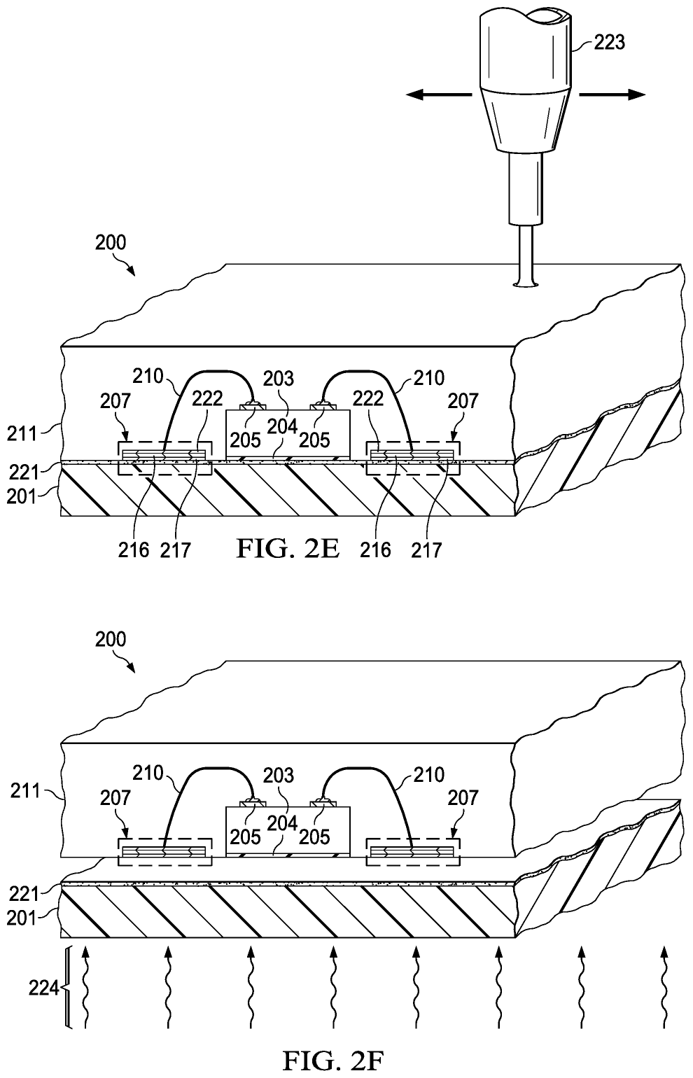

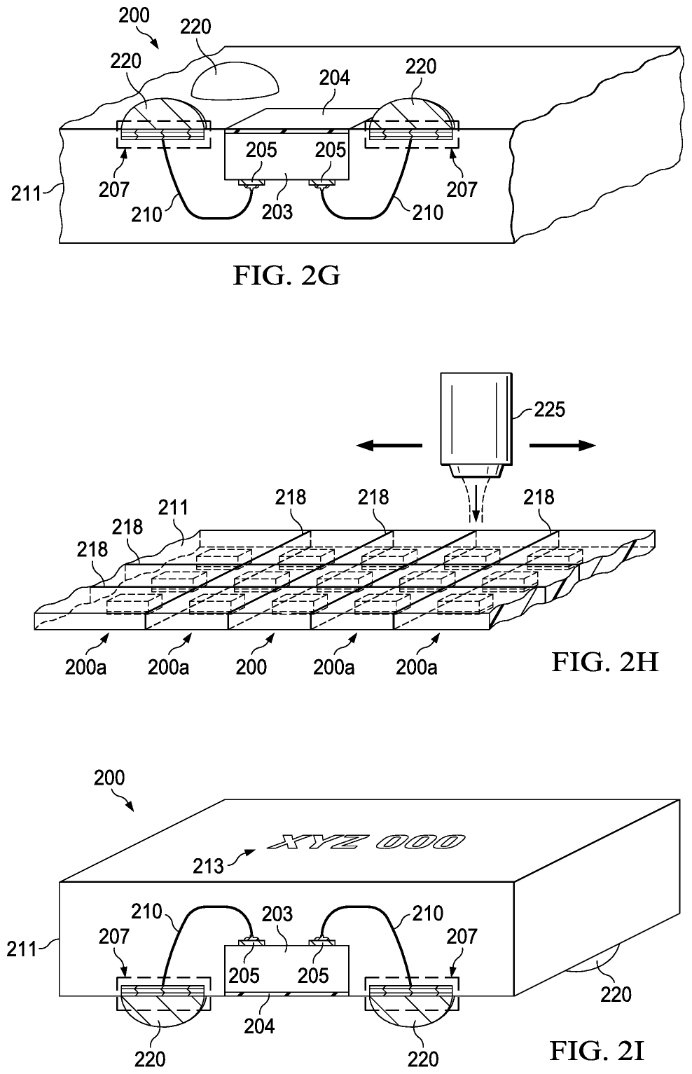

FIG. 2A through FIG. 2I include perspectives, cross sections, and a top view of a microelectronic device having a fan-out chip scale package, depicted in stages of another example method of formation. Referring to FIG. 2A, formation of the microelectronic device (200) begins by acquiring a carrier(201). The carrier (201) includes one or more materials suitable as a substrate for forming wire bond studs. In this example, the carrier (201) may be rigid, to facilitate formation of the wire bond studs. The carrier (201) may include, for example, glass, sapphire, silicon, metal, or ceramic. The carrier (201) may have a laminated structure, with a thin, hard surface layer, attached to a mechanically durable substrate. Other compositions and structures for the carrier (201) are within the scope of this example. The carrier (201) may have alignment marks, not shown in FIG. 2A, to assist subsequent placement of die on the carrier (201).

A releasable adhesive (221) is disposed on the carrier (201). The releasable adhesive (221) may include, a photolabile material which exhibits reduced adhesion after exposure to light in a prescribed wavelength band. The photolabile material may be implemented as an ultraviolet (UV) release material, which reduces adhesion of the releasable adhesive (221) upon exposure to UV light. In the case of the releasable adhesive (221) being implemented with a UV release material, the carrier (201) is transmissive to UV light. Other implementations of the releasable adhesive (221), such as including a thermolabile material, which reduces adhesion of the releasable adhesive (221) upon being heated to a prescribed temperature, are within the scope of this example. Thermolabile materials are sometimes referred to as thermal release materials.

Bump bond pads (207) are disposed on the releasable adhesive (221) in areas for the microelectronic device (200) and in separate areas for additional microelectronic devices (200a). The bump bond pads (207) of the instant example may be implemented as preformed metal pads. The bump bond pads (207) may be individually placed on the releasable adhesive (221), or may be applied in a preconfigured pattern using a tape backing. The bump bond pads (207) have areas to maintain current densities below targeted values, to provide a desired reliability for the microelectronic device (200). The bump bond pads (207) of the instant example are disposed on the releasable adhesive (221) without using a photolithographic process, which may advantageously reduce a fabrication cost and a fabrication complexity of the microelectronic device (200).

Referring to FIG. 2B, multiple die (203) are attached to the releasable adhesive (221). One of the die (203) is attached to the carrier (201) in an area for the microelectronic device (200), and additional die (203) are attached to the carrier (201) in separate areas for additional microelectronic devices (200a). The die (203) may be manifested as integrated circuits, discrete semiconductor components, electro-optical devices, MEMS devices, or other microelectronic die. The die (203) may all be substantially similar devices, or may include more than one device type. The die (203) are positioned adjacent to the bump bond pads (207) for the corresponding microelectronic devices (200) and (200a).

FIG. 2C shows the microelectronic device (200) in more detail. The die (203) may have an electrically insulating layer (204) contacting the releasable adhesive (221) to isolate electrical conductors and semiconductor material in the die (203) from exposure to an exterior of the microelectronic device (200). The electrically insulating layer (204) may include, for example, silicon dioxide, silicon nitride, or polyimide. The die (203) may have terminals (205) for electrical connections to components in the die (203). The terminals (205) may be manifested as bond pads, or circuit nodes. The terminals (205) may include materials suitable for wire bonding.

The bump bond pads (207) may include layers to facilitate wire bonding, provide low resistance, and reduce formation of intermetallic compounds. For example, the bump bond pads (207) may include a barrier layer (217) on the releasable adhesive (221) to reduce diffusion of copper in the bump bond pads (207) and tin in a subsequently-formed solder bump, to mitigate formation of copper-tin intermetallic compounds. Formation of copper-tin intermetallic compounds is linked to reduced reliability. The bump bond pads (207) may further include a base layer (216) of copper or a copper alloy, over the barrier layer (217), to provide a desired low resistance in the bump bond pads (207). The base layer (216) may be, for example, 50 microns to 250 microns thick. Copper or a copper alloy is advantageous for the base layer (216), due to a combination of low cost and low resistance, compared to gold, nickel, or silver. The bump bond pads (207) may also include a wire bondable layer (222) over the base layer (216), to provide an oxidation-resistant surface for wire bonding. The wire bondable layer (222) may include, for example, gold or platinum, and may be 100 nanometers to 2 microns thick. The bump bond pads (207) may include an adhesion layer of titanium or a titanium alloy between the base layer (216) and the wire bondable layer (222), to provide adhesion of the wire bondable layer (222) to the base layer (216) and reduce diffusion of copper from the base layer (216) into the wire bondable layer (222).

Wire bonds (210) are formed by a wire bonding process to connect the die (203) to the bump bond pads (207). FIG. 2C depicts the wire bonds (210) as formed using round bond wire. Other types of bond wire, such as ribbon bond wire, are within the scope of this example. The wire bonds (210) may include, for example, copper wire, coated copper wire, gold wire, or aluminum wire. The wire bonds (210) may be formed with ball bonds on the die (203) and stitch bonds on the bump bond pads (207), or may be formed with ball bonds on the bump bond pads (207) and stitch bonds on the die (203).

FIG. 2D is a top view of an example configuration of the microelectronic device (200). In this example configuration, the microelectronic device (200) includes first bump bond pads (207a) having a round shape. The first bump bond pads (207a) may have minimum lateral dimensions (208) of 150 microns to 300 microns. The term “lateral” refers to a direction parallel to a face of the carrier (201) on which the bump bond pads (207) of FIG. 2C are formed. The minimum lateral dimensions (208) may be selected to maintain current density through the first bump bond pads (207a), during operation of the microelectronic device (200), below a target value, to provide a desired level of reliability. The first bump bond pads (207a) may be appropriate for signals to and from the die (203).

In this example configuration, the microelectronic device (200) further includes second bump bond pads (207b) having an elongated shape. The second bump bond pads (207b) may have minimum lateral dimension (208) of 150 microns to 300 microns. The minimum lateral dimensions (208) may be selected to provide mechanical integrity of solder joints on the second bump bond pads (207b). The second bump bond pads (207b) may be appropriate for power and ground connections to the die (203). Multiple wire bonds (210) may be formed to the second bump bond pads (207b), to provide increased current capacity between the die (203) and the second bump bond pads (207b). Other configurations for the microelectronic device (200) are within the scope of this example.

Referring to FIG. 2E, an encapsulation material (211) is formed over the die (203), the wire bonds (210), and the bump bond pads (207). The encapsulation material (211) may include epoxy or other material suitable for protecting the die (203) and the wire bonds (210) from moisture and contamination. The encapsulation material (211) may be formed by an additive process using a material extrusion apparatus (223). Alternatively, the encapsulation material (211) may be formed by injection molding, by press molding, or by other methods. The encapsulation material (211) extends to the carrier (201) adjacent to the die (203) and adjacent to the bump bond pads (207).

Referring to FIG. 2F, the carrier (201) and the releasable adhesive (221) are removed from the microelectronic device (200) by separating the releasable adhesive (221) from the encapsulation material (211) and from the bump bond pads (207). In the case of the releasable adhesive (221) being implemented with a photolabile material, removal of the carrier (201) and the releasable adhesive (221) may be performed in this example using UV light (224) applied through the carrier (201), as indicated in FIG. 2F. In the case of the releasable adhesive (221) being implemented with other materials, other methods for removing the carrier (201) and the releasable adhesive (221) may be used as appropriate. Removal of the releasable adhesive (221) exposes the bump bond pads (207).

FIG. 2G depicts the microelectronic device (200) after the carrier (201) of FIG. 2F is removed, in an inverted orientation with respect to FIG. 2F. An electrically conductive connection material (220) may be formed on the bump bond pads (207). In one version of this example, the electrically conductive connection material (220) may be implemented as a solder. The solder may be formed by disposing solder paste on the bump bond pads (207), followed by a solder reflow process. Alternatively, the solder may be formed by exposing the bump bond pads (207) to molten solder, such as by using a solder bath or a solder fountain.

The microelectronic device (200), and the additional microelectronic devices (200a), shown in FIG. 2B, may be electrically tested at this point. Testing the microelectronic device (200) and the additional microelectronic devices (200a) while they are attached to each other through the encapsulation material (211) may facilitate handling of the microelectronic device (200) and the additional microelectronic devices (200a).

Referring to FIG. 2H, the microelectronic device (200) is singulated from the additional microelectronic devices (200a) by cutting through the encapsulation material (211) in singulation lanes (218) between the microelectronic device (200) and the additional microelectronic devices (200a). The microelectronic device (200) may be singulated by a laser ablation process using a laser (225), as indicated in FIG. 2H. Singulating the microelectronic device (200) may be facilitated by the absence of metal in the singulation lanes (218).

FIG. 2I depicts the microelectronic device (200) after being singulated. A device identification mark (213) may be formed on the encapsulation material (211). The device identification mark (213) may indicate a device type for the microelectronic device (200), and may also indicate results of the electrical testing of the microelectronic device (200), discussed in reference to FIG. 2G.

An electrically conductive connection material (220) may be formed on the bump bond pads (207). The electrically conductive connection material (220) may be implemented as a solder, or may be implemented as an electrically conductive adhesive. Optionally, the electrically conductive connection material (220) may be omitted during formation of the microelectronic device (200), and may be disposed on the bump bond pads (207) later.

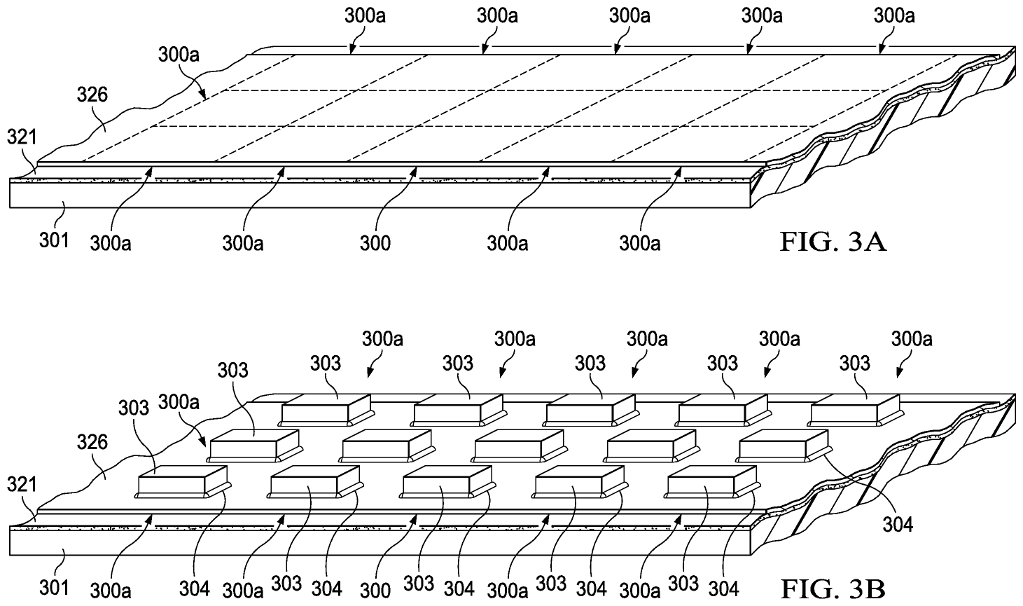

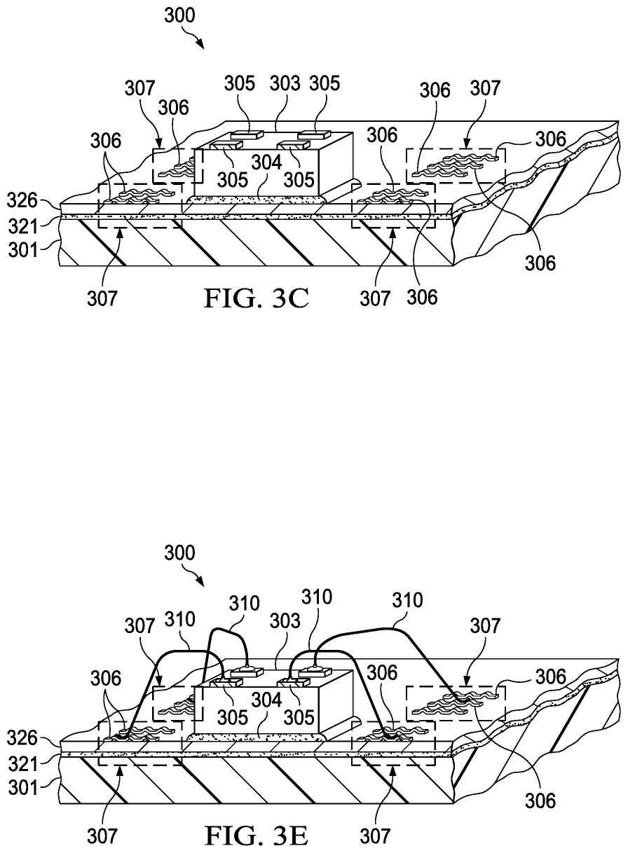

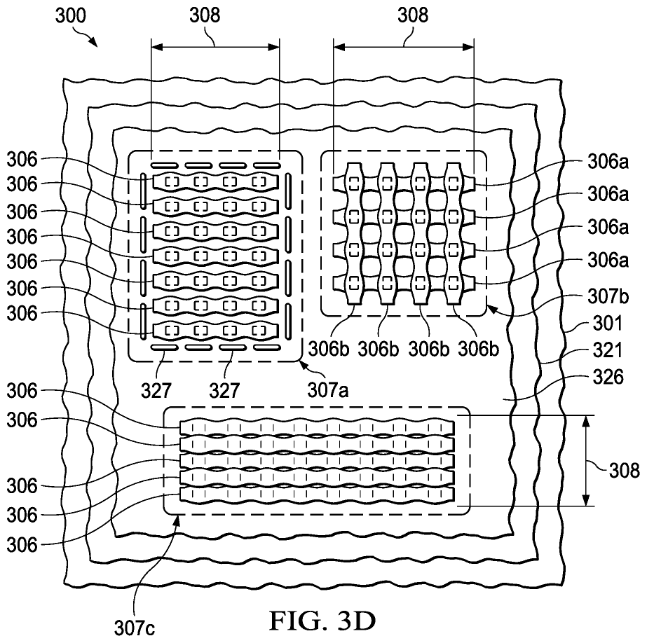

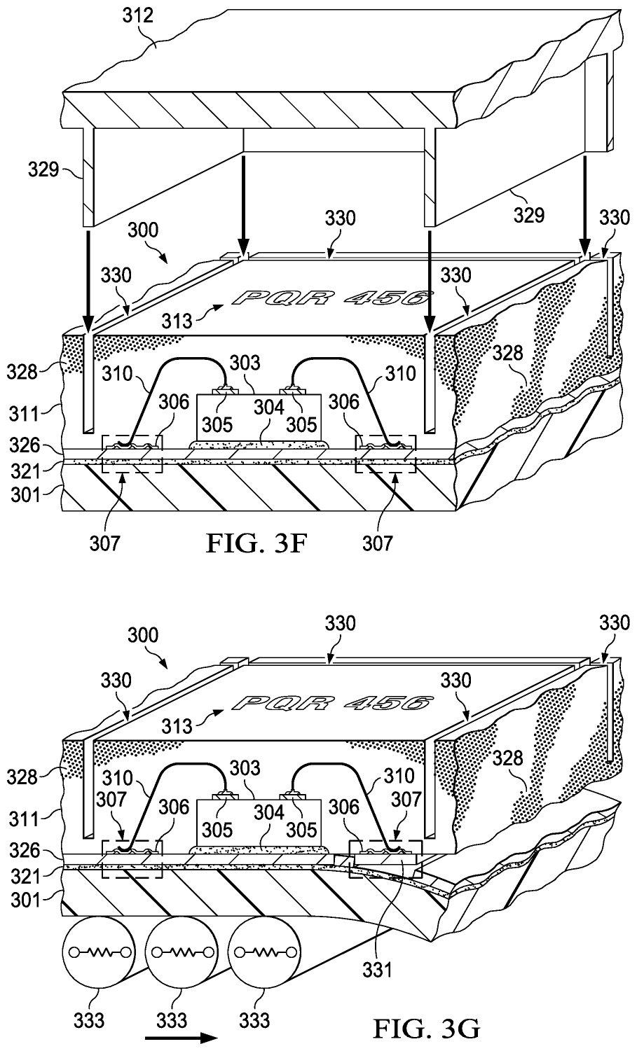

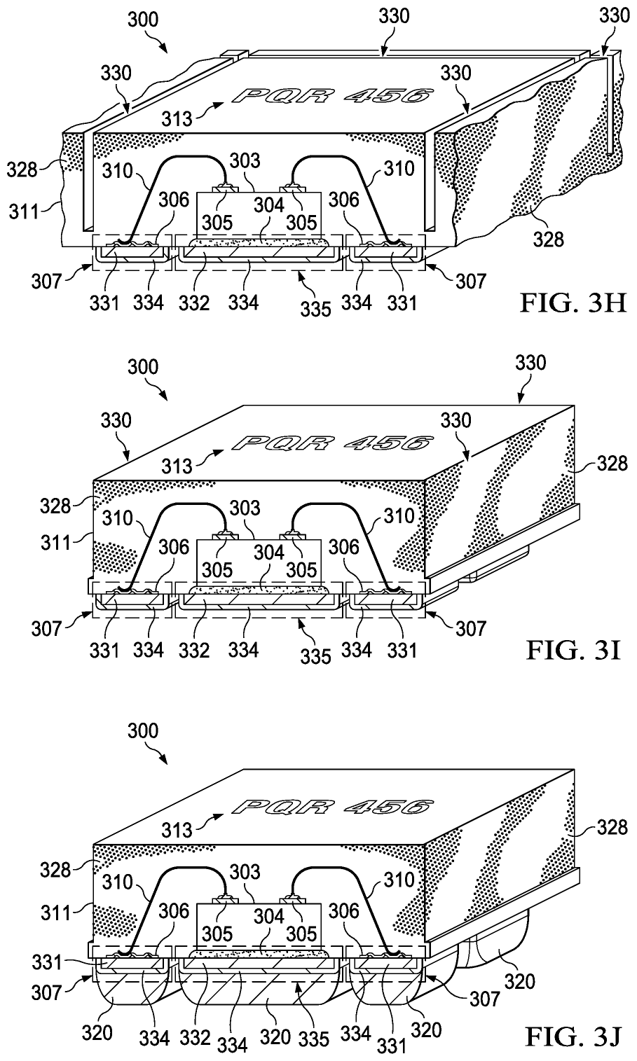

FIG. 3A through FIG. 3J include perspectives, cross sections, and a top view of a microelectronic device having a fan-out chip scale package, depicted in stages of another example method of formation. Referring to FIG. 3A, formation of the microelectronic device (300) begins by acquiring a carrier(301). The carrier (301) includes one or more materials suitable as a substrate for forming ribbon stitch bonds or wire bond studs. In this example, the carrier (301) may be flexible, to facilitate separation of the carrier (301) from the microelectronic device (300). The carrier (301) may include, for example, polyethylene, polypropylene, nylon, or polyurethane. The carrier (301) may have a laminated structure, with fiberglass cloth or such, to provide dimensional integrity. Other compositions and structures for the carrier (301) are within the scope of this example. The carrier (301) may have alignment marks, not shown in FIG. 3A, to assist subsequent placement of die on the carrier (301).

An adhesive (321) is disposed on the carrier (301). The adhesive (321) may be implemented as a permanent adhesive or a releasable adhesive. Implementations of the releasable adhesive may include, for example, a thermolabile material, which reduces adhesion of the adhesive (321) upon being heated to a prescribed temperature. Commercially available adhesives with thermolabile materials have a range of prescribed temperatures, from 75° C. to 200° C.

A pad metal layer (326) is disposed on the adhesive (321). The pad metal layer (326) includes metal suitable for forming wire bond studs or ribbon bond wire stitch strips. The pad metal layer (326) also includes metal suitable for forming a seed layer for a subsequent plating process. The pad metal layer (326) may have several sublayers of metal, for example a protective layer of nickel, gold, platinum, or palladium that contacts the adhesive (321), a base layer of copper or copper alloy on the protective layer, and a wire bondable layer of gold or platinum on the base layer. The base layer may be for example, 50 microns to 250 microns thick. In one version of this example, the pad metal layer (326) may be continuous, with no detachment lines to define areas for bump bond pads. In another version, the pad metal layer (326) may have perforations, indents, creases, crimped lines, thinned lines, or such, to define areas for bump bond pads and to assist separation of the pad metal layer (326) in the areas for the bump bond pads from the remaining pad metal layer (326).

Referring to FIG. 3B, multiple die (303) are attached to the pad metal layer (326). One of the die (303) is attached to the pad metal layer (326) in an area for the microelectronic device (300), and additional die (303) are attached to the pad metal layer (326) in separate areas for additional microelectronic devices (300a). The die (303) may be manifested as integrated circuits, discrete semiconductor components, electro-optical devices, MEMS devices, or other microelectronic die. The die (303) may all be substantially similar devices, or may include more than one device type. The die (303) may be attached to the pad metal layer (326) by a die attach layer (304), or by another material or method. In this example, the die attach layer (304) may be electrically conductive, to provide a substrate contact to the die (303). The die attach layer (304) may be implemented as an adhesive such as epoxy, with metal particles, such as silver particles, nickel particles, or nickel-coated copper particles, to provide a desired level of electrical conductivity.

FIG. 3C shows the microelectronic device (300) in more detail. The die (303) may be electrically connected to the pad metal layer (326) by the die attach layer (304). The die (303) may have terminals (305) for electrical connections to components in the die (303). The terminals (305) may be manifested as bond pads, or circuit nodes. The terminals (305) may include materials suitable for wire bonding.

Ribbon stitch bond strips (306) are formed on the pad metal layer (326) adjacent to the die (303), using a ribbon bond wire bonding process. The ribbon stitch bond strips (306) may be formed by making a series of stitch bonds in a continuous ribbon bond wire, with a wedge bonding tip. The stitch bonds are formed sufficiently close to each other that the pad metal layer (326) remains continuous and attached to the ribbon stitch bond strips (306) when the carrier (301) is subsequently removed. Multiple ribbon stitch bond strips (306) may be formed in groups, with each group providing initial portions of bump bond pads (307). The ribbon stitch bond strips (306) in each bump bond pad (307) may be formed to contact each other, or may be separated by a few microns. Forming the bump bond pads (307) without using a photolithographic process may advantageously reduce fabrication cost and fabrication complexity of the microelectronic device (300).

FIG. 3D depicts example configurations of the ribbon stitch bond strips (306) in the bump bond pads (307) of FIG. 3C. A first bump bond pad (307a) may have a parallel non-contacting configuration, with ribbon stitch bond strips (306) arranged in parallel. Adjacent ribbon stitch bond strips (306) in the first bump bond pad (307a) may be separated. The ribbon stitch bond strips (306) in the first bump bond pad (307a) are electrically connected to each other through the pad metal layer (326). Adjacent ribbon stitch bond strips (306) in the first bump bond pad (307a) may be formed sufficiently close to each other that the pad metal layer (326) remains continuous and attached to the ribbon stitch bond strips (306) when the carrier (301) is subsequently removed. The first bump bond pad (307a) may have a minimum lateral dimension (308) of 150 microns to 300 microns. The term “lateral” refers to a direction parallel to a face of the carrier (301) on which the ribbon stitch bond strips (306) are formed. The minimum lateral dimension (308) may be selected to maintain current density through the first bump bond pad (307a), during operation of the microelectronic device (300), below a target value, to provide a desired level of reliability.

The first bump bond pad (307a) includes a contiguous portion of the pad metal layer (326) contacting the ribbon stitch bond strips (306). The pad metal layer (326) may include pad separation features (327) which surround the first bump bond pad (307a), to facilitate separation of the contiguous portion of the pad metal layer (326) of the first bump bond pad (307a) from a remainder of the pad metal layer (326), when the carrier (301) is removed from the microelectronic device (300). The pad separation features (327) may be implemented as perforations through the pad metal layer (326), indentations in the pad metal layer (326), or other such structures that weaken the pad metal layer (326) around the first bump bond pad (307a).

A second bump bond pad (307b) may have a crossed parallel configuration, with first ribbon stitch bond strips (306a) formed parallel to each other, and second ribbon stitch bond strips (306b) formed parallel to each other and perpendicular to the first ribbon stitch bond strips (306a). Each of the first ribbon stitch bond strips (306a) may contact each of the second ribbon stitch bond strips (306b). The first ribbon stitch bond strips (306a) and the second ribbon stitch bond strips (306b) may be formed with open spaces between the first ribbon stitch bond strips (306a) and the second ribbon stitch bond strips (306b), as indicated in FIG. 3D. Adjacent instances of the first ribbon stitch bond strips (306a) and the second ribbon stitch bond strips (306b) may be formed sufficiently close to each other that the pad metal layer (326) remains continuous and attached to the first ribbon stitch bond strips (306a) and the second ribbon stitch bond strips (306b) when the carrier (301) is subsequently removed. The second bump bond pad (307b) may have a minimum lateral dimension (308) of 150 microns to 300 microns, to provide desired level of reliability as explained in reference to the first bump bond pad (307a). The second bump bond pad (307b) may optionally be implemented with the pad separation features (327).

A third bump bond pad (307c) may have a parallel contacting configuration, with ribbon stitch bond strips (306) arranged in parallel. Adjacent ribbon stitch bond strips (306) in the third bump bond pad (307c) may be formed so as to contact each other, as indicated in FIG. 3D. The third bump bond pad (307c) may have a minimum lateral dimension (308) of 150 microns to 300 microns, and may have an elongated shape, with a length significantly longer than the minimum lateral dimension (308), to provide a desired level of reliability as explained in reference to the first bump bond pad (307a). The elongated shape of the third bump bond pad (307c) may be appropriate for power and ground connections to the microelectronic device (300) of FIG. 3C, which commonly conduct significantly more current than signal connections. The third bump bond pad (307c) may optionally be implemented with the pad separation features (327).

Referring to FIG. 3E, wire bonds (310) are formed by a wire bonding process to connect the die (303) to the bump bond pads (307). FIG. 3E depicts the wire bonds (310) as formed using round bond wire. Other types of bond wire, such as ribbon bond wire, are within the scope of this example. The wire bonds (310) may include, for example, copper wire, coated copper wire, gold wire, or aluminum wire. The wire bonds (310) may be formed with ball bonds on the die (303) and stitch bonds on the bump bond pads (307), or may be formed with ball bonds on the bump bond pads (307) and stitch bonds on the die (303).

Referring to FIG. 3F, an encapsulation material (311) is formed over the die (303), the wire bonds (310), and the bump bond pads (307). The encapsulation material (311) may include epoxy or other material suitable for protecting the die (303) and the wire bonds (310) from moisture and contamination. Fill particles (328) may be distributed in the encapsulation material (311). In one version of this example, the fill particles (328) may have a thermal expansion coefficient higher than a thermal expansion coefficient of the die (303), which may provide improved mechanical reliability when the microelectronic device (300) is mounted on a circuit board having a higher thermal expansion coefficient, compared to a similar device with no fill particles (328) in the encapsulation material (311). In another version of this example, the fill particles (328) may have a thermal conductivity higher than a thermal conductivity of the encapsulation material (311), which may provide a reduced operating temperature for the die (303), and thus improved reliability, compared to a similar device with no fill particles (328) in the encapsulation material (311).

In this example, the encapsulation material (311) may be formed by using a press mold (312) having singulation fins (329), which produce singulation trenches (330) in the encapsulation material (311) around a perimeter of the microelectronic device (300). The singulation trenches (330) may facilitate subsequent singulation of the microelectronic device (300) from the additional microelectronic devices (300a) of FIG. 3B. The press mold (312) may have relief features for a device identification mark (313) on a surface of the encapsulation material (311). The encapsulation material (311) extends to the carrier (301) adjacent to the die (303) and adjacent to the bump bond pads (307).

Referring to FIG. 3G, the carrier (301) and the adhesive (321) are removed from the microelectronic device (300). Portions of the pad metal layer (326) contacting the ribbon stitch bond strips (306) remain attached to the ribbon stitch bond strips (306), providing under bump metal pads (331) of the bump bond pads (307). In each bump bond pad (307), the under bump metal pad (331) is continuous across the bump bond pad (307). A portion of the pad metal layer (326) contacting the die attach layer (304) remains attached to the die attach layer (304), providing a substrate contact pad (332), shown in FIG. 3H. Portions of the pad metal layer (326) outside of areas for the bump bond pads (307) and the substrate contact pad (332) remain attached to the adhesive (321), and are removed from the microelectronic device (300) with the carrier (301) and the adhesive (321).

The adhesive (321) may be weakened to facilitate removal of the carrier (301), while maintaining attachment to the portions of the pad metal layer (326) outside of areas for the bump bond pads (307) and the substrate contact pad (332). In this example, the adhesive (321) may be weakened by heating the adhesive (321) with heated rollers (333).

FIG. 3H depicts the microelectronic device (300) after the carrier (301) of FIG. 3G is removed. An optional supplemental metal layer (334) may be formed on the under bump metal pads (331) and the substrate contact pad (332), to provide lower resistance connections or barriers against intermetallic compounds, resulting from reaction of copper from the bump bond pads (307) with tin from subsequently-formed solder bumps. The supplemental metal layer (334) may be formed by an electroless plating process, for example. The supplemental metal layer (334) may be may be characterized by a conformal configuration on the under bump metal pads (331), resulting from the plating process. Using an electroless plating process may reduce fabrication cost and complexity compared to using an electroplating process, which necessitates a seed layer and plating mask. The supplemental metal layer (334) may include, for example, copper or copper alloy, to provide lower resistance, or nickel, cobalt, palladium, or molybdenum, to provide a barrier layer. The supplemental metal layer (334) on the under bump metal pads (331) is part of the bump bond pads (307). The supplemental metal layer (334) on the substrate contact pad (332) is part of a die connection (335), which includes the substrate contact pad (332) and the die attach layer (304).

The microelectronic device (300), and the additional microelectronic devices (300a), shown in FIG. 3B, may be electrically tested at this point. Testing the microelectronic device (300) and the additional microelectronic devices (300a) while they are attached to each other through the encapsulation material (311) may facilitate handling of the microelectronic device (300) and the additional microelectronic devices (300a).

Referring to FIG. 3I, the microelectronic device (300) is singulated from the additional microelectronic devices (300a) by severing through the encapsulation material (311) below the singulation trenches (330) between the microelectronic device (300) and the additional microelectronic devices (300a). The microelectronic device (300) may be singulated by stressing the encapsulation material (311) below the singulation trenches (330) using singulation tape and a breaking dome, for example. Alternatively, the microelectronic device (300) may be singulated by a water jet process, a laser singulation process, or a saw process. Singulating the microelectronic device (300) may be facilitated by the absence of metal in the encapsulation material (311) below the singulation trenches (330).

Referring to FIG. 3J, an electrically conductive connection material (320) may be formed on the supplemental metal layer (334) on the bump bond pads (307) and the die connection (335). In one version of this example, the electrically conductive connection material (320) may be implemented as a solder. The solder may be formed by disposing solder paste on the bump bond pads (307), followed by a solder reflow process. Alternatively, the solder may be formed by exposing the bump bond pads (307) to molten solder, such as by using a solder bath or a solder fountain.

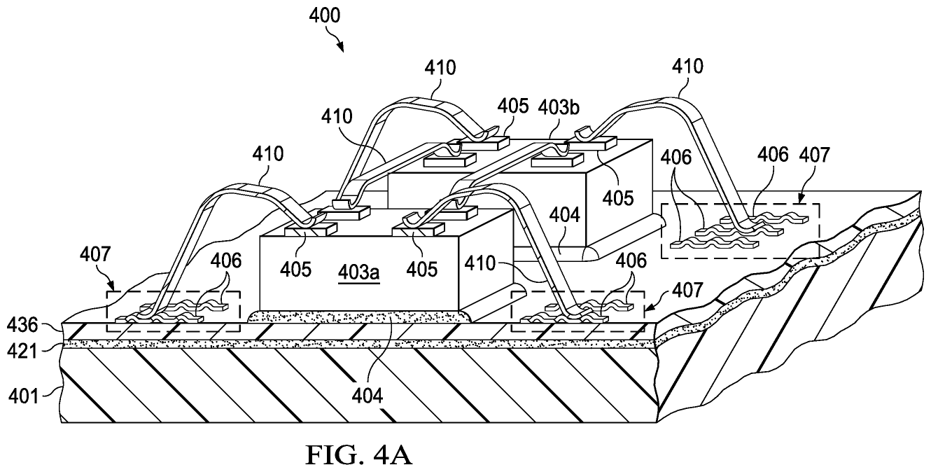

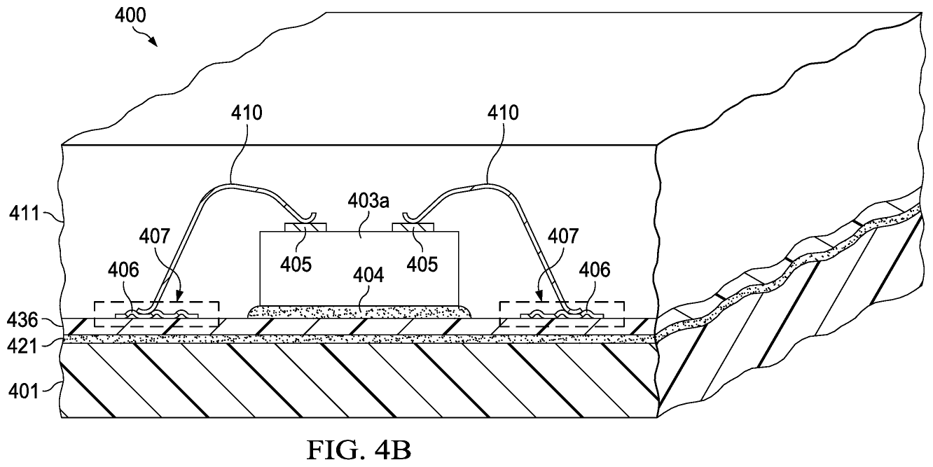

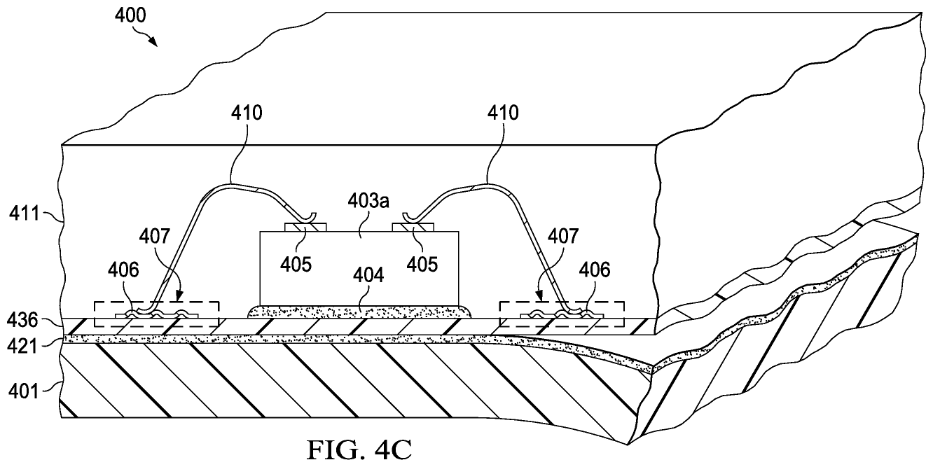

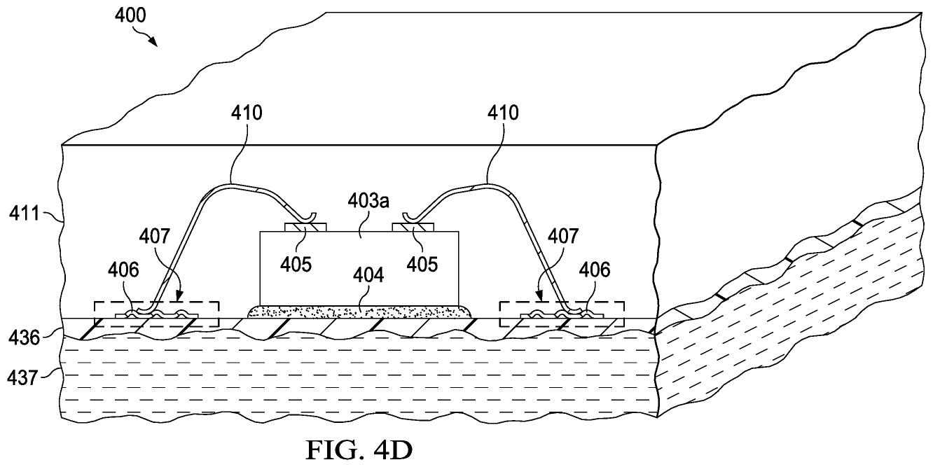

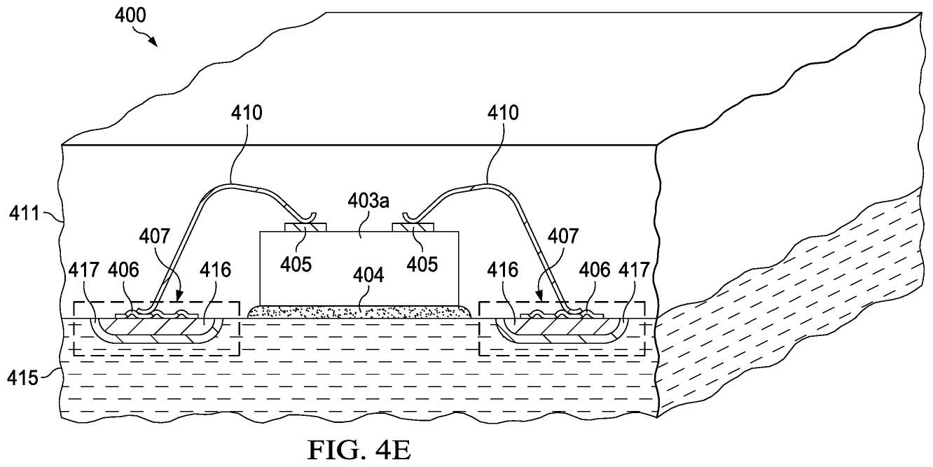

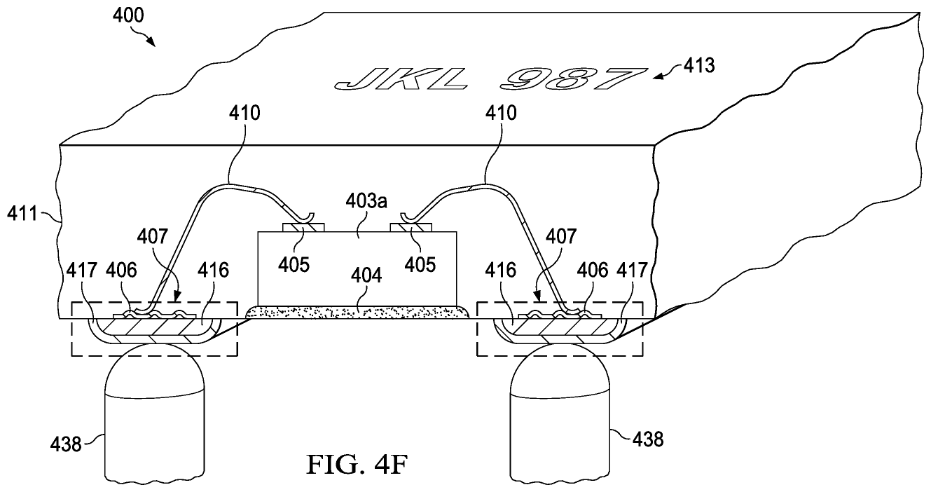

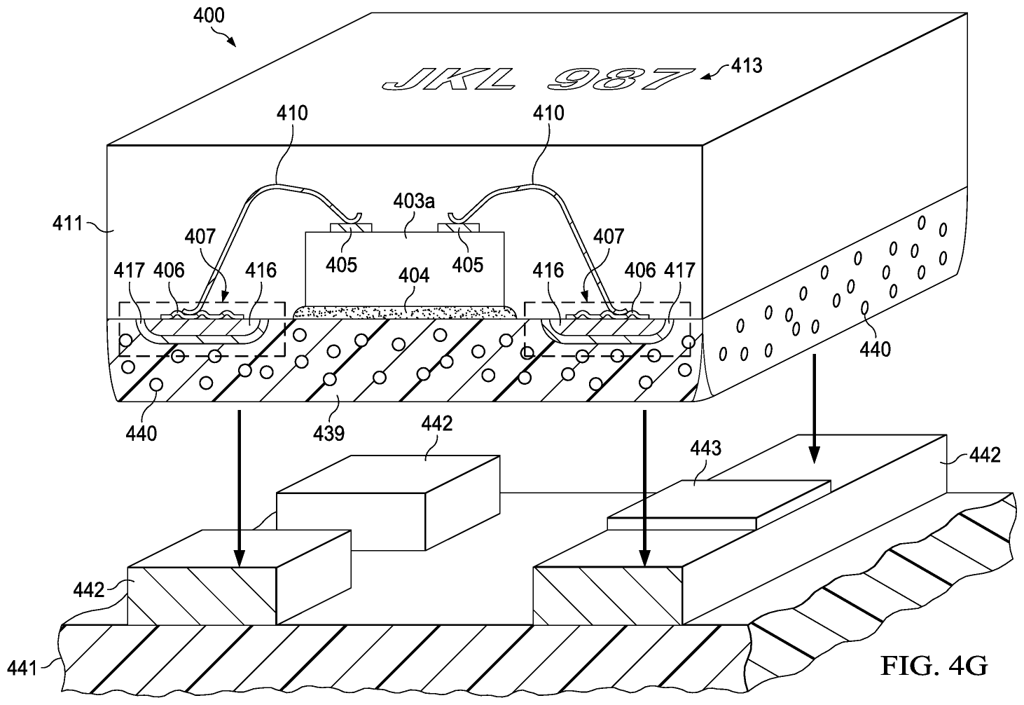

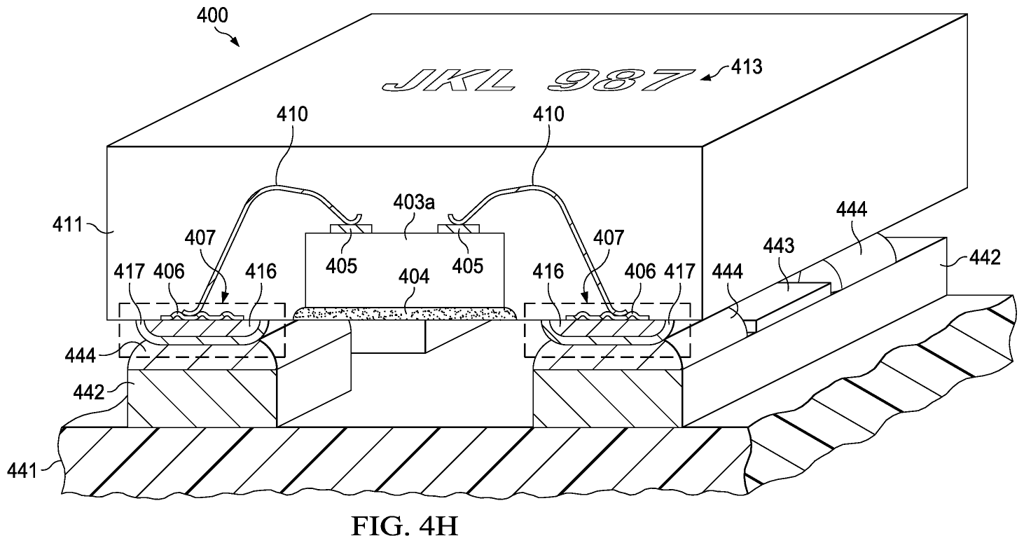

FIG. 4A through FIG. 4H include perspectives and cross sections of a microelectronic device having a fan-out chip scale package, depicted in stages of a further example method of formation. Referring to FIG. 4A, formation of the microelectronic device (400) begins by acquiring a carrier(401). In this example, the carrier (401) may be flexible, to facilitate separation of the carrier (401) from the microelectronic device (400). The carrier (401) may include, for example, polyethylene, polypropylene, nylon, polyurethane, or silicone. The carrier (401) may have a laminated structure, with fiberglass cloth or such, to provide dimensional integrity. Other compositions and structures for the carrier (401) are within the scope of this example. The carrier (401) may have alignment marks, not shown in FIG. 4A, to assist subsequent placement of die on the carrier (401). A releasable adhesive (421) is disposed on the carrier (401). A sacrificial layer (436) is disposed on the releasable adhesive (421). The sacrificial layer (436) includes one or more materials having a hardness suitable for forming ribbon stitch bonds or wire bond studs. The sacrificial layer (436) includes materials which can be removed from the microelectronic device (400) without degrading the microelectronic device (400), for example by a wet etch process. The sacrificial layer (436) may include, for example, aluminum oxide, aluminum nitride, polycrystalline silicon, hydrogen-rich silicon nitride, or phosphosilicate glass (PSG). The sacrificial layer (436) may be 1 micron to 10 microns thick, to facilitate removal from the microelectronic device (400). The releasable adhesive (421) may include, for example, a microsuction tape which has microscopic pores on a face of the releasable adhesive (421) contacting the sacrificial layer (436). The microsuction tape adheres to the sacrificial layer (436) without use of conventional adhesives. The microsuction tape may be permanently affixed to the carrier (401), for example by a permanent adhesive. The microsuction tape may be separated from the sacrificial layer (436) by peeling the carrier (401) from the sacrificial layer (436). Alternatively, the releasable adhesive (421) may include a non-permanent adhesive material, a thermolabile material, or a photolabile material.

In this example, a first die (403a) and a second die (403b) are attached to the sacrificial layer (436) in an area for the microelectronic device (400). Additional die, not shown in FIG. 4A, may be attached to the sacrificial layer (436) in separate areas for additional microelectronic devices, not shown in FIG. 4A. Either of the first die (403a) and the second die (403b) may be manifested as an integrated circuit, a discrete semiconductor component, an electro-optical device, a MEMS device, or other microelectronic die. The first die (403a) and the second die (403b) may be separate types of devices. In this example, the first die (403a) and the second die (403b) may be attached to the sacrificial layer (436) by a die attach layer (404), or by another material or method. In this example, the die attach layer (404) may be electrically non-conductive, to isolate the first die (403a) and the second die (403b). The die attach layer (404) may be implemented as an adhesive such as epoxy, to provide a desired level of electrical isolation.

The first die (403a) and the second die (403b) may have terminals (405) for electrical connections to components in the first die (403a) and the second die (403b). The terminals (405) may be manifested as bond pads, or circuit nodes. The terminals (405) may include materials suitable for wire bonding.

Ribbon stitch bond strips (406) are formed on the sacrificial layer (436) adjacent to the first die (403a) and the second die (403b), using a ribbon bond wire bonding process, to provide initial portions of bump bond pads (407). Multiple ribbon stitch bond strips (406) may be formed in each of the bump bond pads (407). The ribbon stitch bond strips (406) in each bump bond pad (407) may be formed to contact each other, or may be separated by a few microns. The ribbon stitch bond strips (406) may be formed to have any of the configurations disclosed in reference to FIG. 3D. Forming the bump bond pads (407) without using a photolithographic process may advantageously reduce fabrication cost and fabrication complexity of the microelectronic device (400).

Wire bonds (410) are formed by a wire bonding process to connect the first die (403a) and the second die (403b) to the bump bond pads (407). Optionally, one or more of the wire bonds (410) may be formed so as to connect the first die (403a) to the second die (403b), as indicated in FIG. 4A. FIG. 4A depicts the wire bonds (410) as formed using ribbon bond wire. Other types of bond wire, such as round bond wire, are within the scope of this example. The wire bonds (410) may include, for example, copper wire, coated copper wire, gold wire, or aluminum wire.

Referring to FIG. 4B, an encapsulation material (411) is formed over the first die (403a) and the second die (403b), the wire bonds (410), and the bump bond pads (407). The second die (403b) is obscured by the encapsulation material (411) in FIG. 4B. The encapsulation material (411) may include epoxy or other material suitable for protecting the first die (403a), the second die (403b), and the wire bonds (410) from moisture and contamination. The encapsulation material (411) may be formed, for example, by a press molding process, an additive process, or an injection molding process.

Referring to FIG. 4C, the carrier (401) and the releasable adhesive (421) are removed from the microelectronic device (400), leaving the sacrificial layer (436) attached to the microelectronic device (400). In versions of this example in which the releasable adhesive (421) is implemented having the microsuction tape, the carrier (401) and the releasable adhesive (421) may be removed by a peeling process, as indicated in FIG. 4C. In versions of this example in which the releasable adhesive (421) is implemented with photolabile material or thermolabile material, the releasable adhesive (421) may be weakened, for example by exposure to UV radiation or by heating, as appropriate, to facilitate removal of the carrier (401).

Referring to FIG. 4D, the sacrificial layer (436) is removed from the microelectronic device (400), exposing the bump bond pads (407). The sacrificial layer (436) may be removed using a wet etch bath (437) which etches the sacrificial layer (436) without significantly degrading the microelectronic device (400). For example, the wet etch bath (437) may include an aqueous solution of potassium hydroxide, tetramethylammonium hydroxide, or choline hydroxide, which may remove aluminum oxide, aluminum nitride, polycrystalline silicon, hydrogen-rich silicon nitride, or PSG in the sacrificial layer (436) without significantly degrading copper or gold in the ribbon stitch bond strips (406).

Referring to FIG. 4E, a plating process using at least one plating bath (415) forms one or more metal layers of the bump bond pads (407) on the ribbon stitch bond strips (406) where exposed by the encapsulation material (411). The one or more metal layers may include a base layer (416) on the ribbon stitch bond strips (406), and a barrier layer (417) on the base layer (416). The chemistry of the plating bath (415) may be changed to provide desired compositions of the one or more metal layers. The plating process may be implemented as an autocatalytic electroless process or an immersion process, for example. An autocatalytic electroless process may be continued as long as needed to provide a desired thickness of the metal layer. An immersion process is substantially self-limiting, producing a metal layer that is a few nanometers thick. The base layer (416) may include a metal with a high electrical conductivity, such as copper, and may be formed to have a thickness of 50 microns to 150 microns, to provide a low resistance for the bump bond pads (407). The barrier layer (417) may include one or more metals that reduce diffusion between metal in the base layer (416) and subsequently formed solder on the bump bond pads (407). The barrier layer (417) may include, for example, nickel, palladium, cobalt, titanium, or molybdenum. The barrier layer (417) may be formed to be 5 microns to 20 microns thick, for example. The base layer (416) and the barrier layer (417) may be may be characterized by a conformal configuration on the ribbon stitch bond strips (406)), resulting from the plating process. The base layer (416) and the barrier layer (417) are parts of the bump bond pads (407), along with the ribbon stitch bond strips (406), in this example. Forming the base layer (416) and the barrier layer (417) without using a photolithographic process may further reduce the fabrication cost and the fabrication complexity of the microelectronic device (400).

Referring to FIG. 4F, the microelectronic device (400) may be electrically tested. Testing the microelectronic device (400) may be performed by contacting test probes (438) to the bump bond pads (407), and applying test signals and biases to the microelectronic device (400) through the test probes (438).

A device identification mark (413) may be formed on the encapsulation material (411). The device identification mark (413) may indicate a device type for the microelectronic device (400), and may also indicate results of the electrical testing of the microelectronic device (400).

Referring to FIG. 4G, the microelectronic device (400) is singulated from other devices in the encapsulation material (411), by cutting through the encapsulation material (411) around a perimeter of the microelectronic device (400). The microelectronic device (400) may be singulated by a saw process, a laser singulation process which ablates the encapsulation material (411), a water jet process, or other singulation process.

In this example, a solder anisotropic conductive film (439) is applied to the microelectronic device (400), contacting the bump bond pads (407). The solder anisotropic conductive film (439) may include solder particles (440) in an adhesive binder. The solder anisotropic conductive film (439) may be applied in a tape format, or may be applied in a paste format. The solder anisotropic conductive film (439) is commercially available from various suppliers. The microelectronic device (400) is positioned on a circuit substrate (441) having traces (442). The circuit substrate (441) may be implemented as a printed circuit board, a chip carrier, for example. The circuit substrate (441) may include solder resist (443) on the traces (442) to define areas for subsequently-formed solder connections. The microelectronic device (400) is positioned on the circuit substrate (441) so that the bump bond pads (407) are aligned with the traces (442) and the solder anisotropic conductive film (439) contacts the traces (442).

Referring to FIG. 4H, the solder anisotropic conductive film (439) of FIG. 4G is heated, causing the solder particles (440) of FIG. 4G to melt and collect in solder connections (444) that connect the bump bond pads (407) with the traces (442). Remaining material of the solder anisotropic conductive film (439), including the adhesive binder, is not shown in FIG. 4H to more clearly show the solder connections (444).

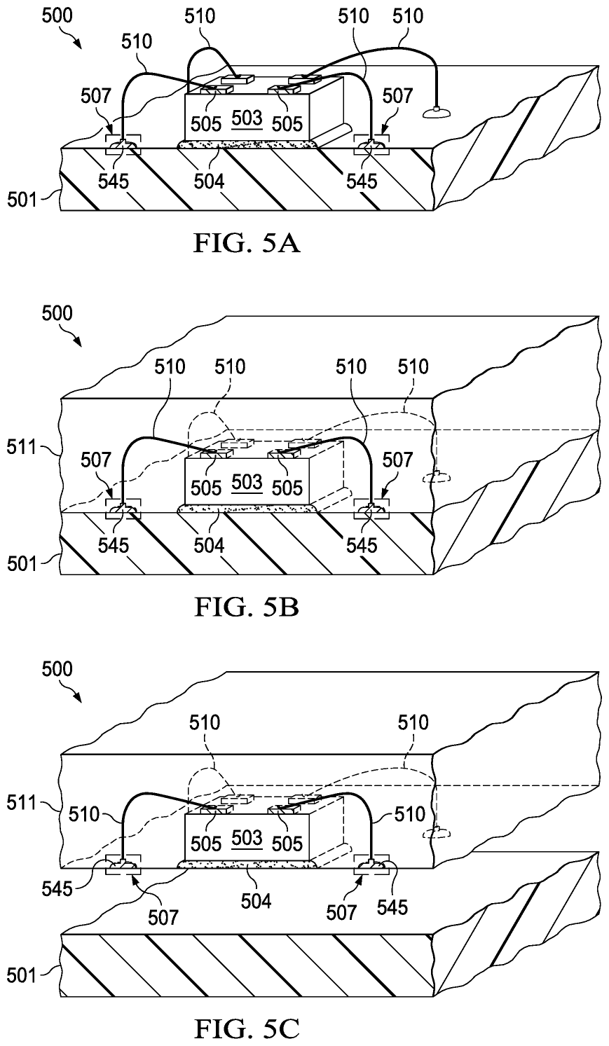

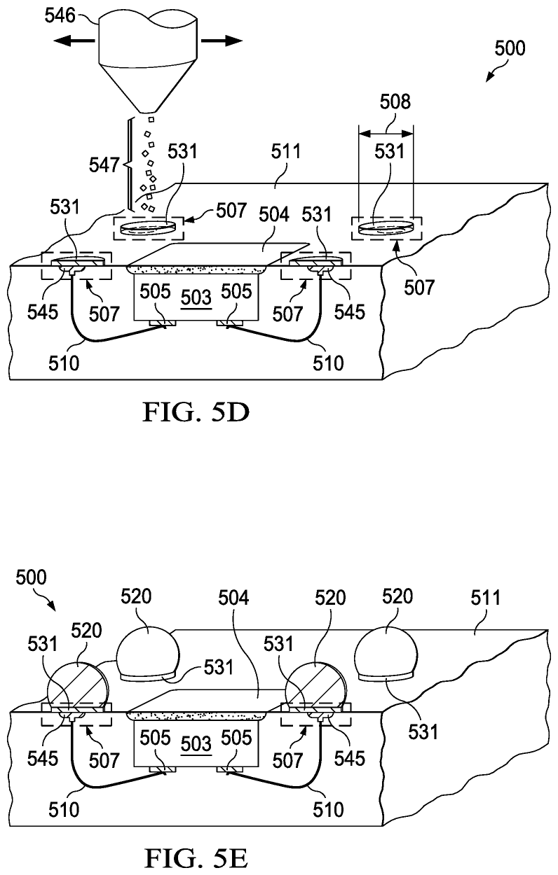

FIG. 5A through FIG. 5E include perspectives, cross sections, and a top view of a microelectronic device having a fan-out chip scale package, depicted in stages of another example method of formation. Referring to FIG. 5A, formation of the microelectronic device (500) begins by acquiring a carrier(501). The carrier (501) may be implemented according to any of the examples disclosed herein, including the carrier (101) of FIG. 1A, the carrier (201) of FIG. 2A, the carrier (301) of FIG. 3A, or the carrier (401) of FIG. 4A.

A die (503) is attached to the carrier (501) in an area for the microelectronic device (500). The die (503) may be manifested as integrated circuits, discrete semiconductor components, electro-optical devices, MEMS devices, or other microelectronic die. The die (503) may be attached to the carrier (501) by a die attach layer (504), or by another material or method. In this example, the die attach layer (504) may be electrically non-conductive, to isolate the die (503). The die attach layer (504) may be implemented as an adhesive such as epoxy, to provide a desired level of electrical isolation. Additional die, not shown in FIG. 5A, may be attached to the carrier (501) in separate areas for additional microelectronic devices, not shown in FIG. 5A.

The die (503) may have terminals (505) for electrical connections to components in the die (503). The terminals (505) may be manifested as bond pads, or circuit nodes. The terminals (505) may include materials suitable for wire bonding.

Wire bonds (510) are formed by a wire bonding process to form ball bonds (545) on the carrier (501) adjacent to the die (503). The ball bonds (545) on the carrier (501) provide initial portions of bump bond pads (507) of the microelectronic device (500). The wire bonds (510) may terminate in stitch bonds on the terminals (505), as depicted in FIG. 5A. Alternatively, wire bond studs may be formed on the terminals (505), and the wire bonds (510) may terminate in stitch bonds on the wire bond studs, a configuration sometimes referred to as a reverse stand-off stitch bond. FIG. 5A depicts the wire bonds (510) as formed by round bond wire, however, ribbon bond wire may be used to form the wire bonds (510).

Referring to FIG. 5B, an encapsulation material (511) is formed over the die (503), the wire bonds (510), and the bump bond pads (507). The encapsulation material (511) may include epoxy or other material suitable for protecting the die (503) and the wire bonds (510) from moisture and contamination. The encapsulation material (511) may be formed, for example, by a press molding process, an additive process, or an injection molding process.

Referring to FIG. 5C, the carrier (501) is separated from the microelectronic device (500). The carrier (501) may be separated from the microelectronic device (500) according to any of the examples disclosed herein, depending on the composition and structure of the carrier (501). Flexible implementations of the carrier (501) may be separated from the microelectronic device (500) as disclosed in reference to FIG. 1H, FIG. 3G, or FIG. 4C. Rigid implementations of the carrier (501) may be separated from the microelectronic device (500) as disclosed in reference to FIG. 2F. The ball bonds (545) of the bump bond pads (507) are exposed after the carrier (501) is separated from the microelectronic device (500).

Referring to FIG. 5D, under bump metal pads (531) of the bump bond pads (507) are formed on the encapsulation material (511), contacting the ball bonds (545) where exposed by the encapsulation material (511). FIG. 5D shows the microelectronic device in an inverted orientation relative to FIG. 5C. The under bump metal pads (531) may be formed by an additive process, using an electrostatic deposition apparatus (546), as depicted in FIG. 5D. The electrostatic deposition apparatus (546) may dispense electrically conductive particles (547) onto the ball bonds (545). The electrically conductive particles (547) may include, for example, copper particles, nickel particles, palladium particles, gold particles, graphene flakes, mxene flakes of metal carbides or metal nitrides, or carbon nanotubes. The under bump metal pads (531) may be formed by other additive processes, such as a material extrusion process, a material jetting process, or a screen printing process. The under bump metal pads (531) are formed without using a photolithographic process, which may advantageously reduce a fabrication cost and a fabrication complexity of the microelectronic device (500). The under bump metal pads (531) may have one or more sublayers of electrically conductive material, for example, a base layer of copper or copper alloy, graphene flakes, mxene flakes, or carbon nanotubes, contacting the ball bonds (545), and a barrier layer of nickel, cobalt, or molybdenum on the base layer. The base layer may be for example, 50 microns to 250 microns thick. The under bump metal pads (531) may have lateral dimensions sufficiently large to provide reliable bump bond pads (507). The term “lateral” refers to a direction parallel to a face of the encapsulation material (511) on which the under bump metal pads (531) are formed. For example, the under bump metal pads (531) may have minimum lateral dimensions (508) of 150 microns to 300 microns.

Referring to FIG. 5E, an electrically conductive connection material (520) may be formed on the bump bond pads (507). The electrically conductive connection material (520) may be implemented as a solder, or may be implemented as an electrically conductive adhesive. Optionally, the electrically conductive connection material (520) may be disposed on the bump bond pads (507) after forming the microelectronic device (500), for example, during an assembly process in which the microelectronic device (500) is connected to a circuit substrate.

Various features of the examples disclosed herein may be combined in other manifestations of example microelectronic devices. For example, multiple die may be included in the example microelectronic devices disclosed in reference to FIG. 1A through FIG. 1K, FIG. 2A through FIG. 2I, FIG. 3A through FIG. 3J, and FIG. 5A through FIG. 5E, similar to the example disclosed in reference to FIG. 4A through FIG. 4H. Encapsulation material may be formed on the example microelectronic devices disclosed in the examples herein by any of the methods disclosed in reference to FIG. 1A through FIG. 1K, FIG. 2A through FIG. 2I, and FIG. 3A through FIG. 3J. Singulation may be performed by any of the methods disclosed in reference to FIG. 1A through FIG. 1K, FIG. 2A through FIG. 2I, and FIG. 3A through FIG. 3J. Testing of the example microelectronic devices may be performed at any stage of formation, and is not limited to the method disclosed in reference to FIG. 4A through FIG. 4H. Device identification marks may be formed on the microelectronic devices at any stage of formation, and is not limited to specific steps disclosed in reference to FIG. 1A through FIG. 1K, FIG. 2A through FIG. 2I, FIG. 3A through FIG. 3J, FIG. 4A through FIG. 4H, and FIG. 5A through FIG. 5E. Elements of the example microelectronic devices described herein, such as the bump bond pads, the wire bonds, and the encapsulation material, may be formed according to methods disclosed with regard to analogous elements in the following commonly assigned U.S. patent applications: U.S. patent application Ser. No. 12/______, Attorney Docket Number TI-78742, filed concurrently with this application, U.S. patent application Ser. No. 12/______, Attorney Docket Number TI-78743, filed concurrently with this application, and U.S. patent application Ser. No. 12/______, Attorney Docket Number TI-78745, filed concurrently with this application. These commonly assigned U.S. patent applications are incorporated herein by reference but are not admitted to be prior art with respect to the present invention by their mention in this section.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a first die;
bump bond pads, wherein the bump bond pads are free of photolithographically-defined structures;
wire bonds connecting the first die to the bump bond pads;
an encapsulation material surrounding the wire bonds, at least partially surrounding the first die and contacting the first die, and contacting the bump bond pads; and
an electrically conductive connection material disposed on the bump bond pads, wherein the electrically conductive connection material is outside of the encapsulation material.

2. The microelectronic device of claim 1, wherein each of the bump bond pads includes a plurality of wire stud bonds.

3. The microelectronic device of claim 1, wherein each of the bump bond pads includes an under bump metal pad, wherein the under bump metal pad is continuous across the bump bond pad containing the under bump metal pad.

4. The microelectronic device of claim 1, wherein the electrically conductive connection material includes a solder.

5. The microelectronic device of claim 1, further including a second die, wherein the second die is at least partially surrounded and contacted by the encapsulation material.

6. The microelectronic device of claim 1, wherein each of the bump bond pads includes a plurality of ribbon stitch bond strips.

7. The microelectronic device of claim 1, wherein each of the bump bond pads includes plated metal, wherein the plated metal conforms to contours of electrically conductive elements of the bump bond pads contacting the plated metal.

8. The microelectronic device of claim 1, further including fill particles distributed in the encapsulation material, wherein the fill particles have a thermal expansion coefficient higher than a thermal expansion coefficient of the first die.

9. The microelectronic device of claim 1, further including fill particles distributed in the encapsulation material, wherein the fill particles have a thermal conductivity higher than a thermal conductivity of the encapsulation material.

10. The microelectronic device of claim 1, wherein the microelectronic device is free of electrically conductive leads extending to lateral surfaces of the encapsulation material, the lateral surfaces being perpendicular to a surface of the encapsulation material contacting the bump bond pads.

11. A method of forming a microelectronic device, comprising:
acquiring a carrier;
disposing a first die on the carrier;
forming at least portions of bump bond pads on the carrier, by a method free of a photolithographic process;
forming wire bonds between the first die and the at least portions of the bump bond pads;
forming an encapsulation material over the first die and the wire bonds, wherein the encapsulation material contacts the at least portions of the bump bond pads; and
removing the carrier, wherein the at least portions of the bump bond pads are exposed at a surface of the encapsulation material.

12. The method of claim 11, wherein a releasable adhesive is disposed on the carrier prior to disposing the first die on the carrier.

13. The method of claim 12, wherein the releasable adhesive includes a photolabile material.

14. The method of claim 12, wherein the releasable adhesive includes a thermolabile material.

15. The method of claim 11, wherein forming the at least portions of the bump bond pads includes forming a plurality of wire stud bonds on the carrier.

16. The method of claim 11, wherein preformed metal pads are disposed on the carrier prior to forming the wire bonds, the preformed metal pads providing at least portions of the bump bond pads.

17. The method of claim 11, wherein:
a pad metal layer is disposed on the carrier prior to forming the wire bonds; and
removing the carrier includes removing a portion of the pad metal layer, wherein portions of the pad metal layer contacting the at least portions of the bump bond pads remain attached to the at least portions of the bump bond pads.

18. The method of claim 11, further including plating metal on the at least portions of the bump bond pads after removing the carrier.

19. The method of claim 11, further including disposing solder on the bump bond pads.

20. The method of claim 11, further including disposing a second die on the carrier prior to forming the encapsulation material.
